(19) United States
(12) Patent Application Publication
(10) Pub. No.: US 2008/0130227 A1
(43) Pub. Date: Jun. 5, 2008

(54) Electronic apparatus

(75) Inventor: Takeshi Yokomizo, Fuchu-shi (JP)

Correspondence Address: PILLSBURY WINTHROP SHAW PITTMAN, LLP, P.O. BOX 10500, MCLEAN, VA, 22102, US

(73) Assignee: KABUSHIKI KAISHA TOSHIBA, Tokyo (JP)

(21) Appl. No.: 11/976,151

(22) Filed: Oct. 22, 2007

(30) Foreign Application Priority Data
Nov. 30, 2006 (JP) 2006-324804

(51) Int. Cl. H05K 7/20

(52) U.S. Cl. 361/695

(57) ABSTRACT

According to one embodiment, an electronic apparatus includes a circuit board, an MPU which is provided on the circuit board and produces heat, an attachment stay which is provided on the circuit board and has a plurality of attachment areas, and a fan unit which is attached to at least one selected from the plurality of attachment areas of the attachment device, and cools the MPU.

### CROSS-REFERENCE TO RELATED APPLICATIONS

This application is based upon and claims the benefit of priority from Japanese Patent Application No. 2006-324804, filed Nov. 30, 2006, the entire contents of which are incorporated herein by reference.

### BACKGROUND

1. Field

One embodiment of the invention relates to an electronic apparatus in which a fan unit for cooling electronic components is mounted.

2. Description of the Related Art

In general, in an electronic apparatus such as a personal computer, an IC, an LSI, an MPU, etc. (hereinafter these components are representatively referred to as “MPU”) are disposed on a circuit board. In order to process various multimedia information such as characters, sounds and images, the processing speed and the functions of the MPU have steadily been enhanced.

In the meantime, in the MPU, power consumption increases in accordance with development in integration density and enhancement of functions, and the amount of heat produced during operation tends to increase accordingly.

In order to promote radiation of heat of the MPU, a motor-driven fan unit is provided within the apparatus (see, e.g. Jpn. Pat. Appln. KOKAI Publication No. 2000-13070).

In the prior art, however, the position of attachment of the fan unit is fixed at one location. As a result, in the case where the location of heat production has varied due to alteration of a function mode or in the case where the temperature within the apparatus has risen due to additional provision of an optional unit, such a problem arises that proper cooling cannot be carried out.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary plan view showing an electronic circuit unit according to an embodiment of the present invention;

FIG. 2 is an exemplary front view of the electronic circuit unit shown in FIG. 1;

FIG. 3 is an exemplary one side view of the electronic circuit unit shown in FIG. 1;

FIG. 4 is an exemplary the other side view of the electronic circuit unit shown in FIG. 1;

FIG. 5 is an exemplary plan view showing a circuit board of the electronic circuit unit shown in FIG. 1;

FIG. 6 is an exemplary one side view of the circuit board shown in FIG. 5;

FIG. 7 is an exemplary plan view showing an attachment stay for attaching a fan unit of the electronic circuit unit shown in FIG. 1;

FIG. 8 is an exemplary front view of the attachment stay shown in FIG. 7;

FIG. 9 is an exemplary one side view of the attachment stay shown in FIG. 7;

FIG. 10 is an exemplary the other side view of the attachment stay shown in FIG. 7;

FIG. 11 is an exemplary view illustrating an assembly method of the electronic circuit unit shown in FIG. 1;

FIG. 12 is an exemplary view illustrating the assembly method of the electronic circuit unit shown in FIG. 1;

FIG. 13 is an exemplary plan view showing the electronic circuit unit which has been assembled;

FIG. 14 shows an exemplary state in which the position of attachment of the fan unit is changed to one end side of the attachment stay;

FIG. 15 shows an exemplary state in which the position of attachment of the fan unit is changed to the other end side of the attachment stay;

FIG. 16 is an exemplary plan view showing a state in which a plurality of fan units are attached to the attachment stay;

FIG. 17 is an exemplary view showing an attachment structure of a fan unit, according to a second embodiment of the present invention;

FIG. 18 shows an exemplary state in which the position of attachment of the fan unit shown in FIG. 17 is changed to one end side of the attachment stay;

FIG. 19 shows an exemplary state in which the position of attachment of the fan unit shown in FIG. 17 is changed to the other end side of the attachment stay; and

FIG. 20 shows an exemplary state in which a plurality of fan units are attached to the attachment stay.

### DETAILED DESCRIPTION

Various embodiments according to the invention will be described hereinafter with reference to the accompanying drawings. In general, according to one embodiment of the invention, an electronic apparatus comprising: a circuit board; an electronic component which is provided on the circuit board and produces heat; an attachment device which is provided on the circuit board and has a plurality of attachment areas; and a fan unit which is attached to at least one selected from the plurality of attachment areas of the attachment device, and cools the electronic component.

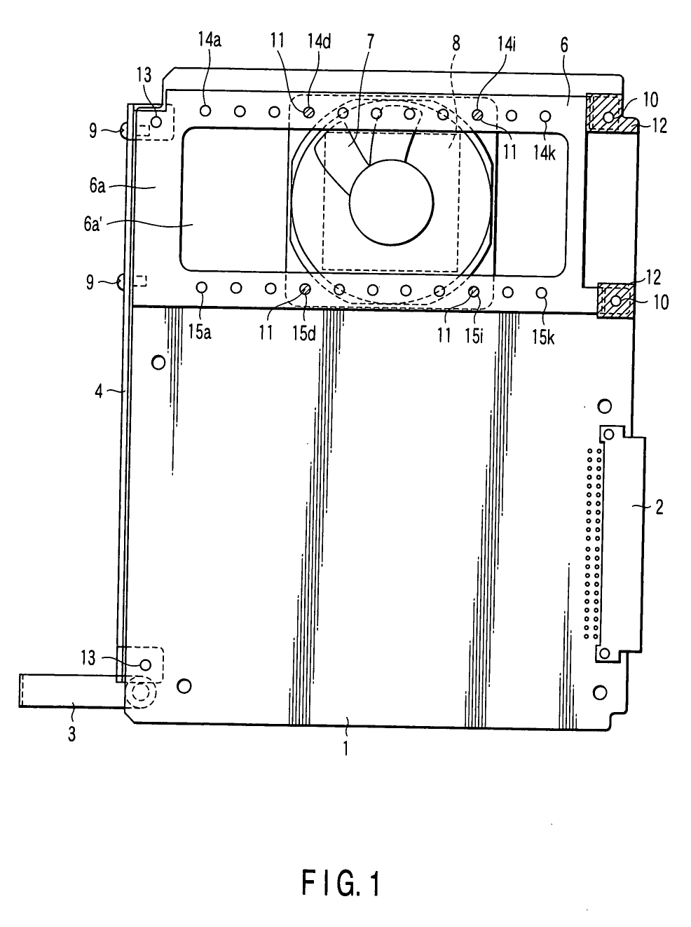

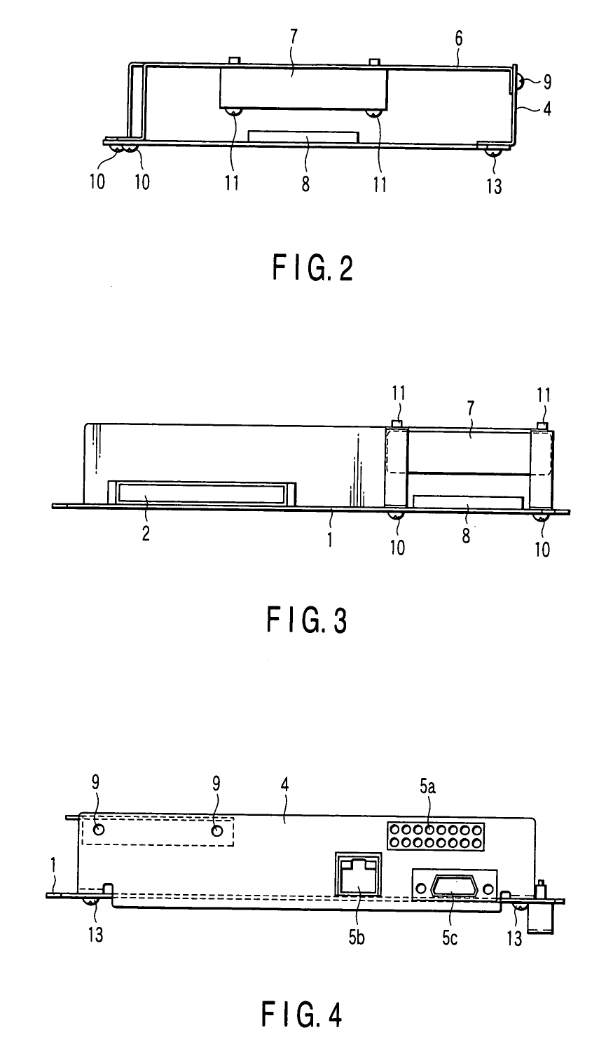

FIG. 1 is a plan view showing an electronic circuit unit of an electronic apparatus, such as a portable computer, according to an embodiment of the invention. FIG. 2 is a front view of the electronic circuit unit, FIG. 3 is one side view of the electronic circuit unit, and FIG. 4 is the other side view of the electronic circuit unit.

The electronic circuit unit includes a circuit board 1. A connector 2 for connection to a motherboard of the electronic apparatus is provided on the circuit board 1. In addition, a clamp 3 for removal from the electronic apparatus is provided on the circuit board 1.

A panel 4 is disposed upright on one side portion of an upper surface of the circuit board 1. A lower end portion of the panel 4 is fixed to the circuit board 1 by means of fixing screws 13. Various electric components 5a to 5c are attached to the panel 4.

An MPU (Micro-Processing Unit) 8 is provided, as an electronic component that produces heat, is provided on one end side of the upper surface of the circuit board 1. The power consumption of the MPU 8 increases in accordance with development in integration density and enhancement of functions, and the amount of heat produced during operation tends to increase. Thus, the MPU 8 requires cooling.

Further, an attachment stay 6 is provided as an attachment device on one end side of the upper surface of the circuit board 1. A fan unit 7 is attached to a back side of the attachment stay 6. The fan unit 7 is disposed in the state in which the fan unit 7 is spaced apart from, and is opposed to, the MPU 8. One end portion of the attachment stay 6 is fixed to the panel 4 by means of fixing screws 9, and lower parts of leg portions (to be described later), which are provided at the other end portion of the attachment stay 6, are fixed to the circuit substrate 1 by means of screws 10.

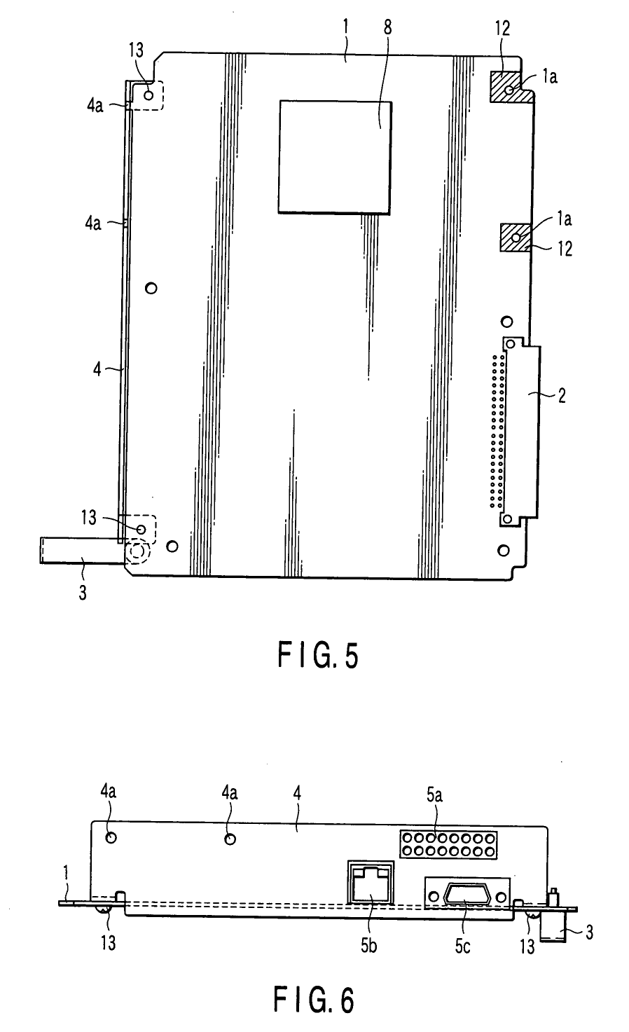

FIG. 5 is a plan view showing the circuit board 1 of the above-described electronic circuit unit. FIG. 6 is one side view of the circuit board 1. Screw passage holes la for passing the fixing screws 13 are formed in component-mounting/pattern-formation prohibition areas 12 of the circuit board 1. In addition, screw passage holes 4a for passing the fixing screws 9 are formed in the panel 4.

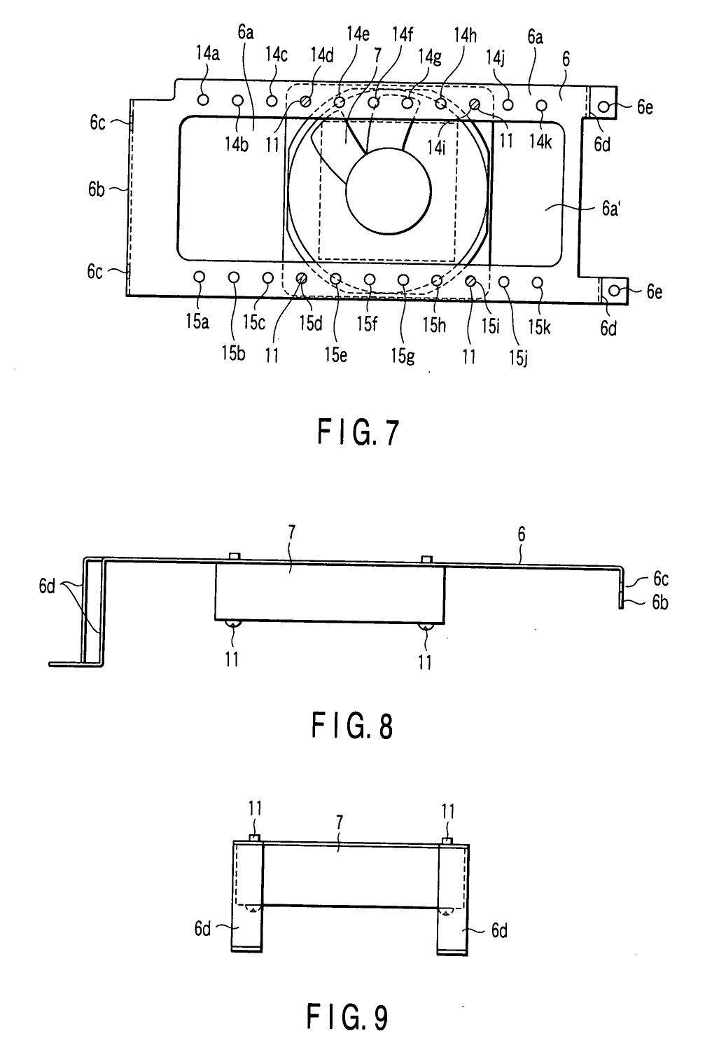

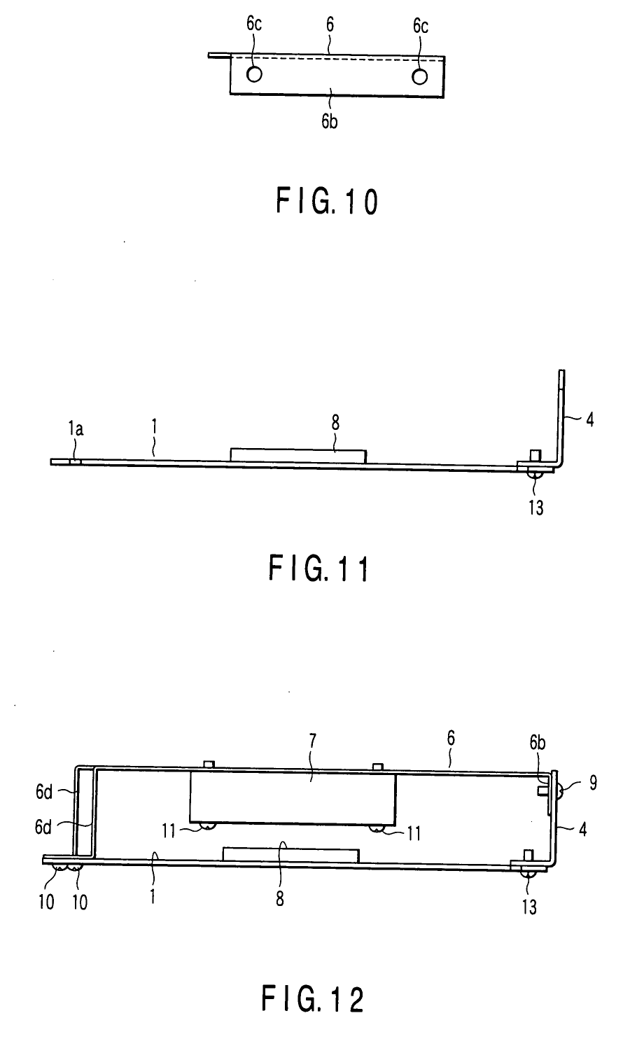

FIG. 7 to FIG. 10 show the above-described attachment stay 6 and the fan unit 7 that is attached to the attachment stay 6.

The attachment stay 6 has a rectangular base plate portion 6a, and an opening portion 6a′ is formed in the base plate portion 6a. A plurality (22) of screw holes 14a-14k and 15a-15k are formed at predetermined intervals in the base plate portion 6a along both side edge portions of the opening portion 6a′.

Four fixing screws 11 are inserted in four corner portions of the fan unit 7. The inserted end portions of the fixing screws 11 are driven into, e.g. four screw holes 14d, 14i, 15d and 15i, which are selected from the screw holes 14a-14k and 15a-15k in the base plate portion 6a. Thereby, the fan unit 7 is fixed.

Specifically, four of the screw holes 14a-14k and 15a-15k are arbitrarily selected, and the fixing screws 11 are driven into the four screw holes. Thereby, the fan unit 7 can be attached to a desired one of a plurality of attachment areas.

On the other hand, a bent portion 6b is formed at one end portion of the attachment stay 6, and screw holes 6c for inserting the fixing screws 9 are formed in the bent portion 6b. A pair of leg portions 6d are formed at the other end portion of the attachment stay 6, and screw holes 6e for inserting the fixing screws 10 are formed in lower end portions of the leg portions 6d.

Next, a method of attaching the attachment stay 6 to the circuit board 1 is described.

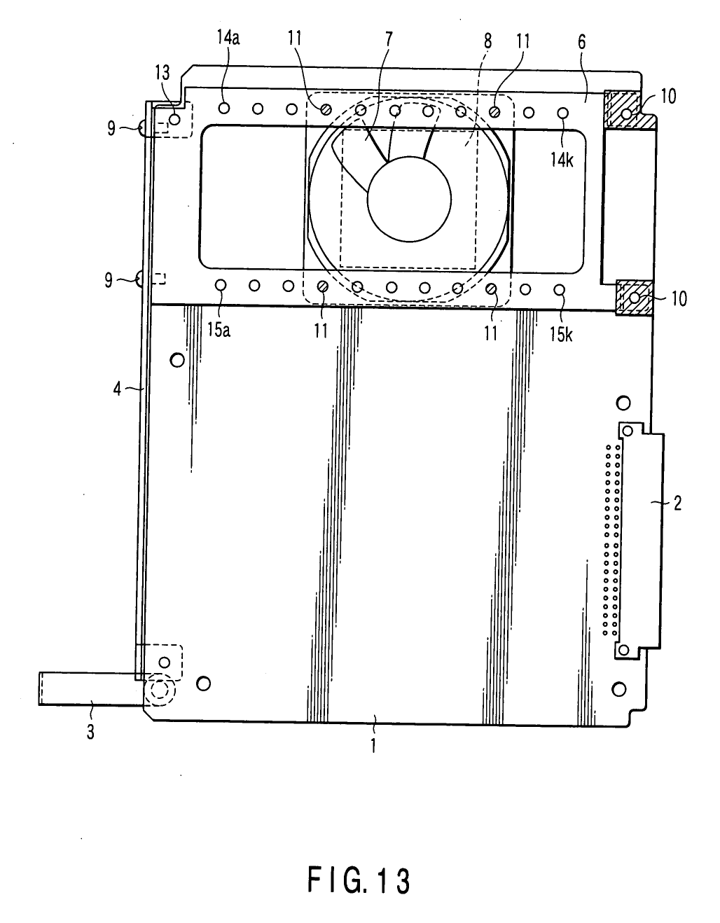

To begin with, as shown in FIG. 11, the panel 4 is fixed to one side portion of the circuit board 1 by the fixing screws 13. Then, as shown in FIG. 12, the attachment stay 6 is disposed to be opposed to, and spaced apart from, the circuit board 1, and the bent portion 6b at one side portion of the attachment stay 6 is fixed to the panel 4 by the fixing screws 9. Further, the lower end portions of the leg portions 6d at the other side portion of the attachment stay 6 are fixed to the circuit board 1 by the fixing screws 10. Thereby, as shown in FIG. 13, the fan unit 7 is attached to the circuit board 1 in the state in which the fan unit 7 is opposed to, and spaced apart from, the MPU 8.

If the fan unit 7 is driven in the state in which the attachment stay 6 is attached, cooling air is blown to cool the MPU 8.

In the meantime, in the electronic circuit unit, if the function mode is altered, the location where heat is produced may vary. In such a case, proper cooling is not expectable if the fan unit 7 is positioned to face the MPU 8, as shown in FIG. 13.

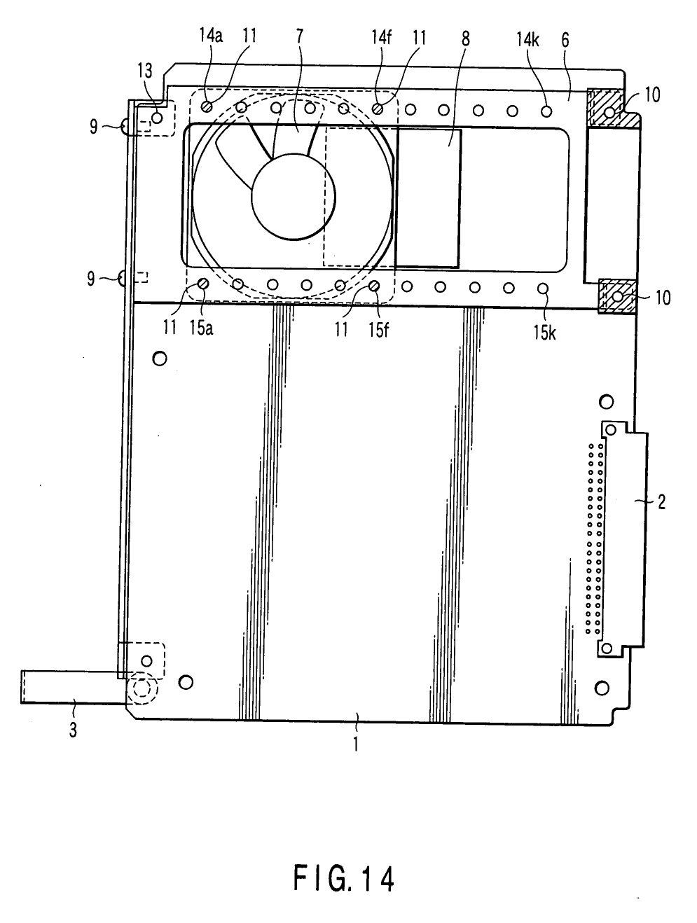

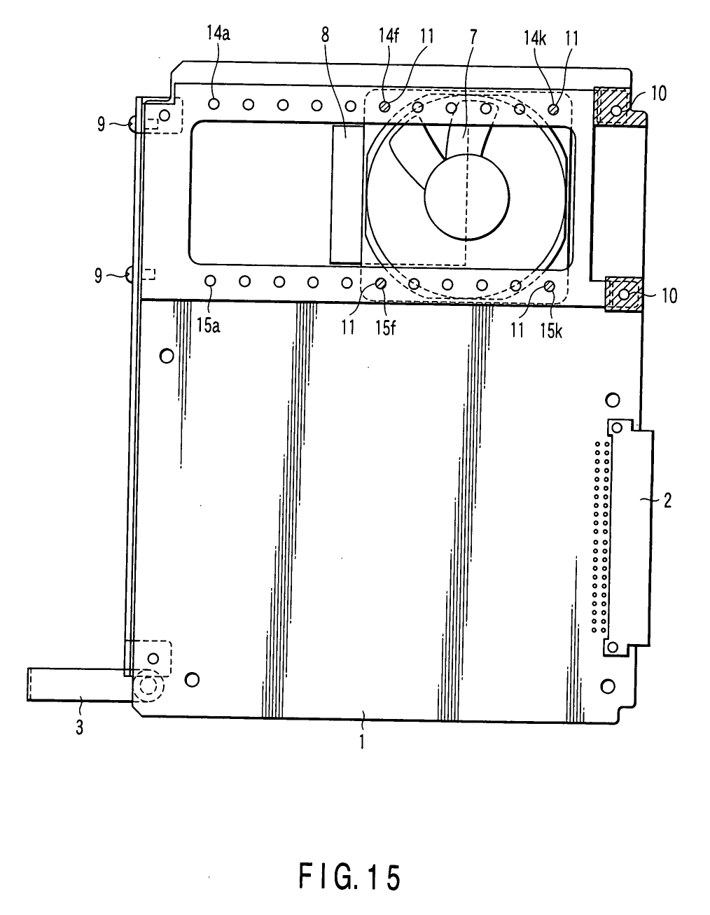

In the present embodiment, if the location of heat production has varied, the position of attachment of the fan unit 7 is changed, for example, to one end side of the attachment stay 6 as shown in FIG. 14, or to the other end side of the attachment stay 6 as shown in FIG. 15.

For example, in the case where the fan unit 7 is attached to an attachment area at one end side of the attachment stay 6, the screw holes 14a, 14f, 15a and 15f, for instance, are selected and the fixing screws 11 are driven into these screw holes 14a, 14f, 15a and 15f. Thereby, the fan unit 7 is fixed.

In the case where the fan unit 7 is attached to an attachment area at the other end side of the attachment stay 6, the screw holes 14f, 14k, 15f and 15k, for instance, are selected and the fixing screws 11 are driven into these screw holes 14f, 14k, 15f and 15k. Thereby, the fan unit 7 is fixed.

As has been described above, by varying the attachment position of the fan unit 7 in accordance with the change of the location of heat production, cooling air can properly be fed to the location of heat production, and good cooling can be carried out.

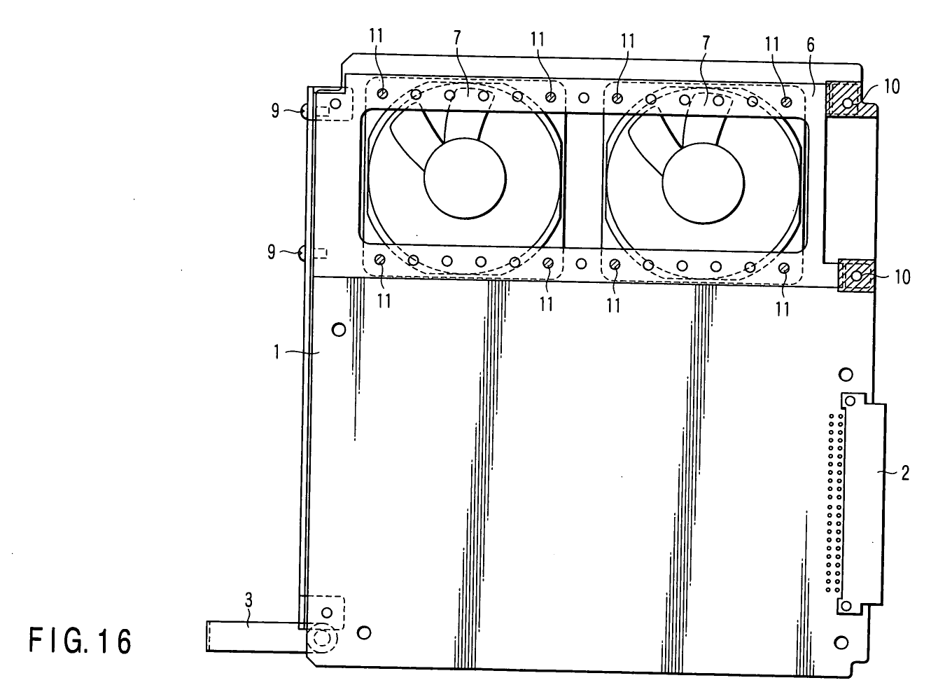

Besides, according to the present embodiment, a plurality (two) of fan units 7 can be attached, as shown in FIG. 16.

If an optional unit is additionally provided in the electronic circuit unit, the temperature in the electronic circuit unit rises. In such a case, a sufficient cooling effect may not be expected with a single fan unit 7. Thus, by attaching a plurality of fan units 7, the cooling performance can be increased, and the rise in temperature in the electronic circuit unit can surely be prevented.

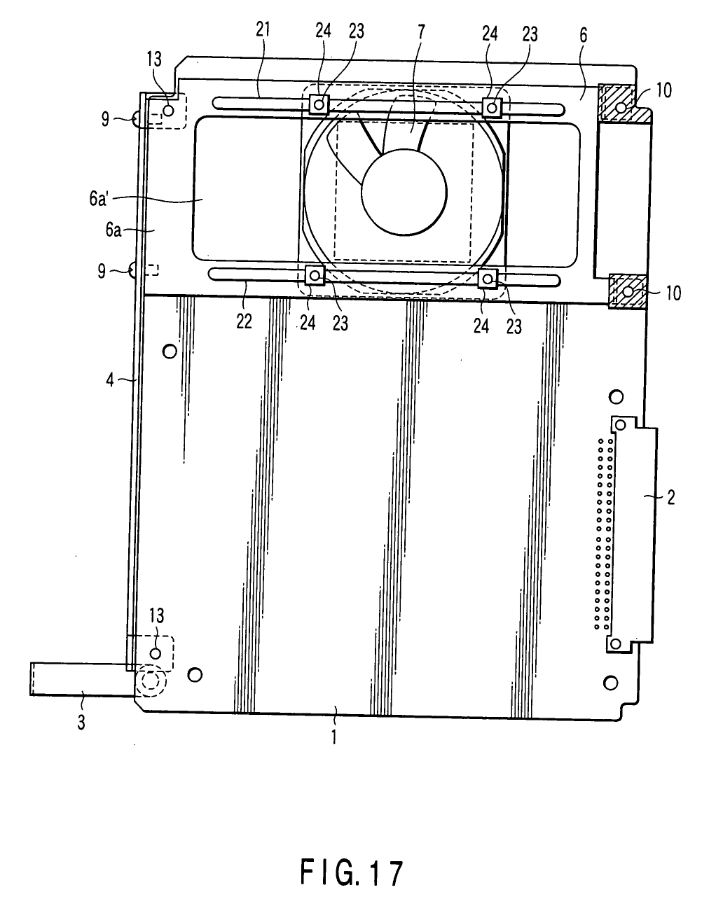

FIG. 17 shows a second embodiment of the present invention.

The parts common to those in the above-described first embodiment are denoted by like reference numerals, and a detailed description thereof is omitted here.

In the above-described first embodiment, a plurality of screw holes 14a-14k and 15a-15k are formed in the attachment stay 6, and the fixing screws 11 are driven into arbitrarily selected screw holes, thereby attaching the fan unit 7. In the second embodiment, long holes 21 and 22 are formed in an upper surface of the attachment stay 6 along both side edge portions of the opening portion 6a′. Bolts 23 serving as fixing members are inserted in the long holes 21 and 22, and inserted end portions of the bolts 23 are engaged with nuts 24. Thereby, the fan unit 7 is attached.

According to the second embodiment, too, the attachment position of the fan unit 7 can be varied.

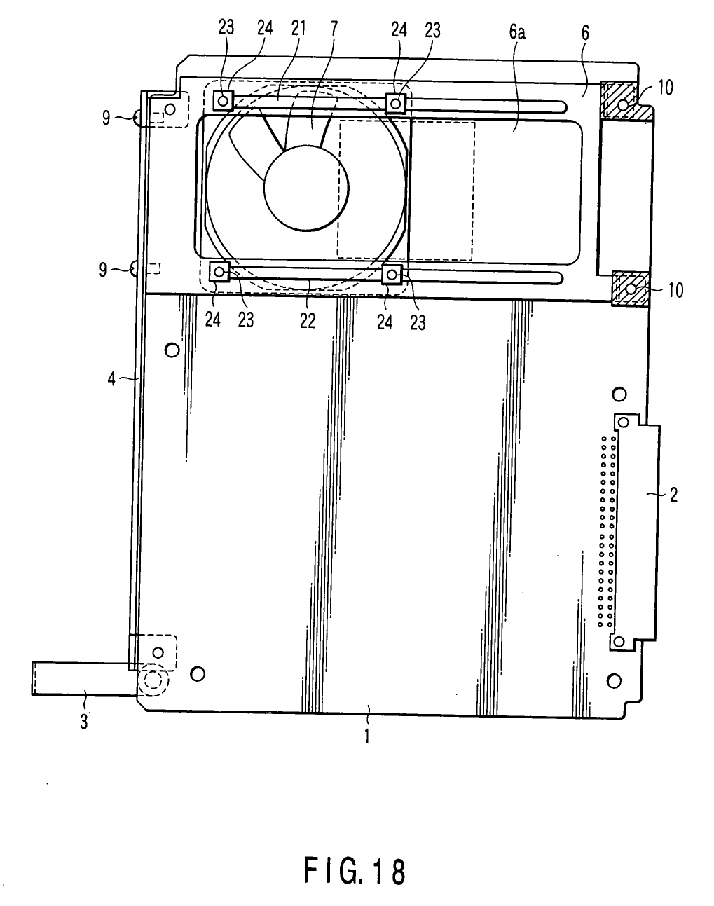

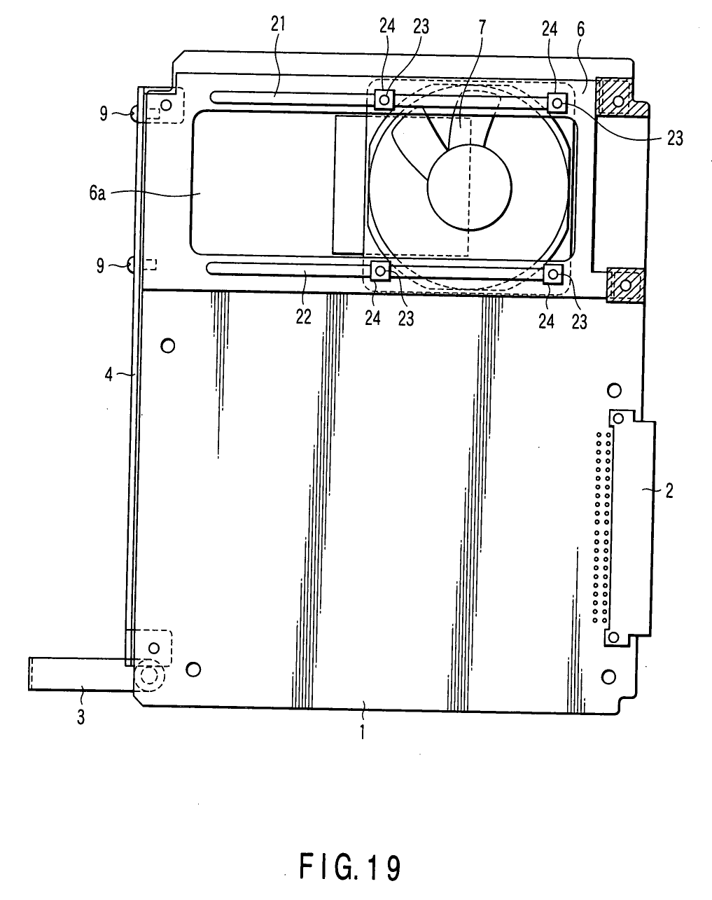

For example, in the case where the attachment position of the fan unit 7 is changed to one end side of the attachment stay 6 as shown in FIG. 18, the fan unit 7 is first positioned on the one end side of the attachment stay 6 and then the bots 23 are inserted in the four corner portions of the fan unit 7 and in the long holes 21 and 22. The inserted end portions of the bots 23 are engaged with the nuts 24, and thus the fan unit 7 is fixed.

In the case where the attachment position of the fan unit 7 is changed to the other end side of the attachment stay 6 as shown in FIG. 19, the fan unit 7 is first positioned on the other end side of the attachment stay 6 and then the bots 23 are inserted in the four corner portions of the fan unit 7 and in the long holes 21 and 22. The inserted end portions of the bots 23 are engaged with the nuts 24, and thus the fan unit 7 is fixed.

In the second embodiment, like the first embodiment, by varying the attachment position of the fan unit 7 in accordance with the change of the location of heat production, cooling air can properly be fed to the location of heat production, and good cooling can be carried out.

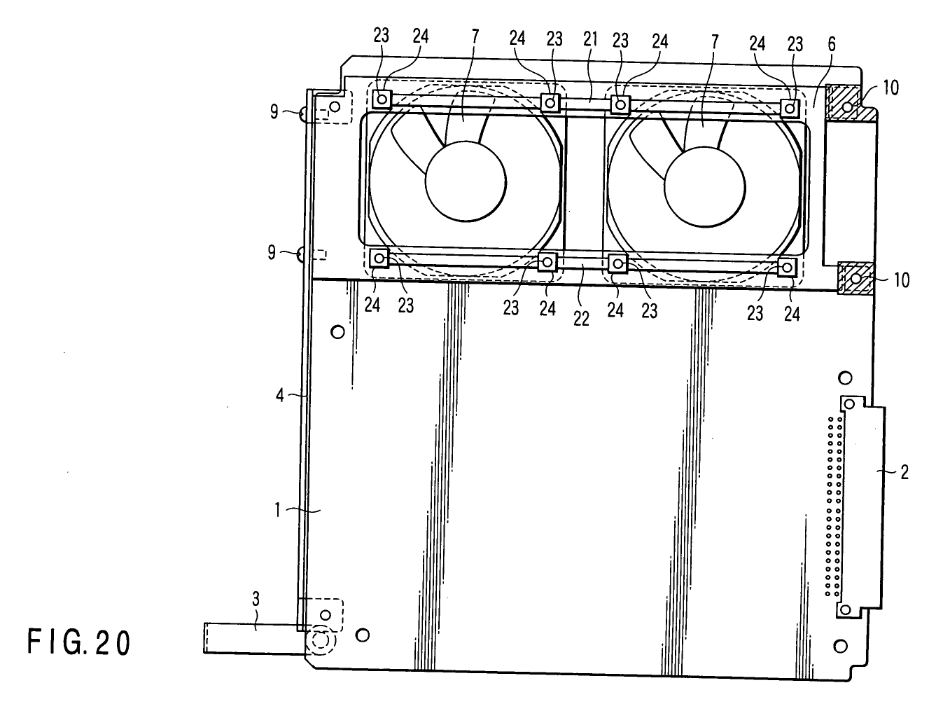

According to the second embodiment, too, a plurality (two) of fan units 7 can be attached, as shown in FIG. 20. By attaching a plurality of fan units 7, the amount of cooling air can be increased, and the rise in temperature in the electronic circuit unit can surely be prevented.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An electronic apparatus comprising:
a circuit board;
an electronic component which is provided on the circuit board and produces heat;
an attachment device which is provided on the circuit board and has a plurality of attachment areas; and
a fan unit which is attached to at least one selected from the plurality of attachment areas of the attachment device, and cools the electronic component.

2. The electronic apparatus according to claim 1, wherein the attachment device includes an attachment stay and a plurality of screw holes provided in the attachment stay, and some of the plurality of screw holes are selected and fixing screws for fixing the fan unit are driven into the selected screw holes, whereby the fan unit is attached to the attachment stay.

3. The electronic apparatus according to claim 2, wherein the attachment stay includes a rectangular base plate portion, an opening portion is formed in the base plate portion, and the plurality of screw holes are formed at predetermined intervals along both side edge portions of the opening portion.

4. The electronic apparatus according to claim 3, wherein the attachment stay has a bent portion at one side of the base plate portion and a leg portion at the other side of the base plate portion, and the attachment stay is fixed to the circuit board via the bent portion and the leg portion.

5. The electronic apparatus according to claim 1, wherein the attachment device includes an attachment stay and long holes provided in the attachment stay, and fixing members for fixing the fan unit are inserted in arbitrary parts of the long holes, whereby the fan unit is attached to the attachment stay.

6. The electronic apparatus according to claim 5, wherein the attachment stay includes a rectangular base plate portion, an opening portion is formed in the base plate portion, and the long holes are formed along both side edge portions of the opening portion.

7. The electronic apparatus according to claim 6, wherein the attachment stay has a bent portion at one side of the base plate portion and a leg portion at the other side of the base plate portion, and the attachment stay is fixed to the circuit board via the bent portion and the leg portion.
